(19) United States
(12) Patent Application Publication
(10) Pub. No.: US 2024/0130092 A1
(43) Pub. Date: Apr. 18, 2024

(54) DATA CENTER COMPUTER ROOM COOLING SYSTEM AND CONTROL METHOD THEREOF

(71) Applicant: Hebei Qinhuai Data Co., Limited., Zhangjiakou City (CN)

(72) Inventors: Binghua ZHANG, Zhangjiakou City (CN); Mingjiang LI, Zhangjiakou City (CN); Xiaogang SUN, Zhangjiakou City (CN)

(21) Appl. No.: 18/487,979

(22) Filed: Oct. 16, 2023

(30) Foreign Application Priority Data
Oct. 17, 2022 (CN) 202211268326.3

(51) Int. Cl. H05K 7/20; F24F 11/00

(52) U.S. Cl. CPC H05K 7/20827; F24F 11/0008; F24F 2006/001

(57) ABSTRACT

Embodiments of the present disclosure provide a data center computer room cooling system and a control method thereof, relating to the field of heat dissipation technology of the data center computer room. The system includes an indoor subsystem and an outdoor subsystem. The indoor subsystem includes an indoor fan, an indoor air supply outlet, an indoor return air inlet, an indoor wet curtain apparatus and an evaporator. The outdoor subsystem includes an outdoor fan, a fluorine pump condenser, a liquid cooling dry cooler, a compressor, a fluorine pump, an expansion valve, and an outdoor wet curtain apparatus.

### CROSS-REFERENCE TO RELATED APPLICATION

This application claims priority to Chinese Patent Application No. 202211268326.3, titled “DATA CENTER COMPUTER ROOM COOLING SYSTEM AND CONTROL METHOD THEREOF” and filed to the China National Intellectual Property Administration on Oct. 17, 2022, the entire contents of which are incorporated herein by reference.

### TECHNICAL FIELD

The present disclosure relates to the field of heat dissipation technology of a data center computer room, and more particularly, to a data center computer room cooling system and a control method thereof.

### BACKGROUND

In recent years, the development of data centers is moving towards high power and high density, and more and more data centers adopt liquid cooling solutions. Generally, a cold plate liquid-cooling air conditioning system and an air-cooling air conditioning system may be provided, according to business requirements, for a data center computer room adopting cold plate liquid cooling, including using a cold plate module to carry out liquid cooling on CPU and other parts, and using traditional air conditioners to carry out air cooling on hard disks and other parts. That is, the data center computer room may be simultaneously provided with the cold plate liquid-cooling air conditioning system and the air-cooling air conditioning system, and each of the two air conditioning systems bear a portion of heat dissipation demands of the computer room.

In the data center adopting cold plate liquid cooling, generally the two air conditioning systems adopting different cooling principles are configured, deployed and regulated separately because of different operating states and different supply and return water temperatures. As more and more data centers adopting the cold plate liquid cooling solution, coordination and collaborative delivery of the above two air conditioning systems are also increasing. Based on study of heat dissipation technologies of the data center computer room, inventors of the present disclosure have following findings.

Units, outdoor arrangement and pipe connection of the two air conditioners need to be considered in coordination and need to be produced and delivered separately, which is disadvantageous to implementation of data centers required for rapid delivery.

A standalone large-scale fluorine pump unit generally operates under dry conditions, and its comprehensive energy efficiency is 10% to 20% lower than that of an indirect evaporative cooling unit under the same conditions in the same area mainly because of factors such as space and cost impacts, restrictions of condenser dimension, and direct use of outdoor air as heat dissipation sources.

When cold sources of the cold plate liquid cooling adopt cooling towers, more water is consumed, so it is not suitable for areas with strict restrictions on water resource indexes and water-deficient areas. When the cold sources adopt dry coolers, it may be unable to provide sufficient rated heat dissipation capacity when a project site is in extreme operating conditions.

### SUMMARY

To solve some or all problems existing in the prior art, embodiments of the present disclosure provide a data center computer room cooling system and a control method thereof. The technical solutions are as follows.

In a first aspect, there is provided a data center computer room cooling system, which includes an indoor subsystem and an outdoor subsystem. The indoor subsystem includes an indoor fan, an indoor air supply outlet, an indoor return air inlet, an indoor wet curtain apparatus and an evaporator. The outdoor subsystem includes an outdoor fan, a fluorine pump condenser, a liquid cooling dry cooler, a compressor, a fluorine pump, an expansion valve, and an outdoor wet curtain apparatus.

The evaporator is installed between the indoor fan and the indoor wet curtain apparatus, such that under a drive of the indoor fan, indoor air sequentially flows through the indoor fan, the indoor air supply outlet, the evaporator, the indoor wet curtain apparatus and the indoor return air inlet to form a loop.

The outdoor fan is arranged at an outdoor air outlet of the outdoor subsystem, the outdoor wet curtain apparatus is arranged at an outdoor air inlet of the outdoor subsystem, and the fluorine pump condenser is arranged adjacent to the liquid cooling dry cooler, such that under the drive of the outdoor fan, outdoor air flows through the outdoor wet curtain apparatus, the fluorine pump condenser, the liquid cooling dry cooler and the outdoor fan and is discharged to outside.

The fluorine pump condenser, the compressor, the evaporator, the expansion valve and the fluorine pump are sequentially connected through a coolant pipe to form a coolant loop.

Alternatively, a thermal insulation board is arranged between the indoor subsystem and the outdoor subsystem.

Alternatively, the system further includes a support frame for placing and fixing parts of the indoor subsystem and the outdoor subsystem. The fluorine pump condenser and the liquid cooling dry cooler are arranged vertically or horizontally on the support frame.

Alternatively, the indoor wet curtain apparatus and/or the outdoor wet curtain apparatus includes a sprinkler pump, a water inlet pipe, a water discharge pipe, a valve, and a water collecting sump.

The sprinkler pump is arranged above the indoor wet curtain apparatus and/or the outdoor wet curtain apparatus; the valve is installed on the water inlet pipe or the water discharge pipe; and two ends of the water inlet pipe and two ends of the water discharge pipe are respectively connected to the sprinkler pump and the water collecting sump.

Alternatively, the outdoor subsystem further includes an outdoor air inlet louver mounted at the outdoor air inlet.

Alternatively, the system also includes a unit controller mounted on a side wall of the outdoor subsystem.

Alternatively, the coolant loop of the outdoor subsystem is further provided with a cooling water pump, a frequency converter, and a shock absorber.

Alternatively, a projection of the indoor wet curtain apparatus on a plane where the indoor air supply outlet is located completely or partially covers the indoor air supply outlet.

A second aspect provides a control method for a data center computer room cooling system, the control method is applied to the system in the first aspect; and the control method includes:
collecting an outdoor ambient temperature and determining whether the outdoor ambient temperature is lower than a preset temperature threshold;
turning off the outdoor wet curtain apparatus when the outdoor ambient temperature is lower than the preset temperature threshold; and
turning on the outdoor wet curtain apparatus when the outdoor ambient temperature is not lower than the preset temperature threshold.

Alternatively, when the outdoor subsystem is provided with an outdoor air inlet louver, whether the outdoor air enters the outdoor subsystem is controlled by turning on or off the outdoor air inlet louver.

By adopting the above technical solutions, the present disclosure can at least produce following technical effects.

Firstly, cold sources of an air cooling system and cold sources of a liquid cooling system are integrated, and all parts are arranged on one whole support frame, thus achieving integrated delivery of the air cooling system and the liquid cooling system, which can effectively save workload and complexity in construction stages, making a delivery speed more than 25% faster than that of a traditional way. Secondly, by adopting the present disclosure, wet curtain drenching measures can be adopted for an air cooling portion, such that energy efficiency can be improved by 10% to 20% compared with an ordinary large-scale fluorine pump unit. Furthermore, the wet curtain drenching measures and a traditional dry condenser with sufficient capacity are used in a liquid cooling portion, which can ensure that the liquid cooling portion still has sufficient heat dissipation capacity under extreme operating states, and annual operation energy consumption is reduced by more than 10% to 20% compared with the solution of using the traditional dry condenser. Thirdly, according to the present disclosure, the data center computer room cooling system includes the indoor subsystem and the outdoor subsystem, which conforms to a distributed architecture solution of an air conditioner, has better fault tolerance than a traditional capacity unit, and has no fatal influence on the system. Fourthly, when this product is delivered in large scale and in batches, prices of the data center computer room cooling system can be further reduced, which can effectively alleviate a problem of higher prices of cold plate liquid cooling refrigeration systems.

### BRIEF DESCRIPTION OF THE DRAWINGS

To describe the technical solutions of the embodiments of the present disclosure more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a schematic structural diagram of a data center computer room cooling system provided by a first embodiment of the present disclosure;

FIG. 2 is a schematic structural diagram of a data center computer room cooling system provided by a second embodiment of the present disclosure;

FIG. 3 is a cross-sectional view of an outdoor portion of a data center computer room cooling system provided by a third embodiment of the present disclosure.

### DETAILED DESCRIPTION

To make the objectives, technical solutions and advantages of the present disclosure clearer, the embodiments of the present disclosure will be further described below in detail with reference to the accompanying drawings. Terms such as “upper”, “above”, “lower”, “below”, “first end”, “second end”, “one end”, “other end” and the like as used herein, which denote spatial relative positions, describe the relationship of one unit or feature relative to another unit or feature in the accompanying drawings for the purpose of illustration. The terms of the spatial relative positions may be intended to include different orientations of the device in use or operation other than the orientations shown in the accompanying drawings. For example, the units that are described as “below” or “under” other units or features will be “above” other units or features if the device in the accompanying drawings is turned upside down. Thus, the exemplary term “below” can encompass both the orientations of above and below. The device may be otherwise oriented (rotated by 90 degrees or facing other directions) and the space-related descriptors used herein are interpreted accordingly.

In addition, the terms “installed”, “arranged”, “provided”, “connected”, “sliding connection”, “fixed” and “socket” should be understood broadly. For example, the “connection” may be a fixed connection, a detachable connection or integrated connection, a mechanical connection or an electrical connection, a direct connection or indirect connection by means of an intermediary, or an internal connection between two apparatuses, components or constituent parts. For those of ordinary skill in the art, concrete meanings of the above terms in the present disclosure may be understood based on concrete circumstances.

An embodiment of the present disclosure provides a data center computer room cooling system, which includes an indoor subsystem and an outdoor subsystem. The indoor subsystem includes an indoor fan, an indoor air supply outlet, an indoor return air inlet, an indoor wet curtain apparatus and an evaporator. The outdoor subsystem includes an outdoor fan, a fluorine pump condenser, a liquid cooling dry cooler, a compressor, a fluorine pump, an expansion valve, and an outdoor wet curtain apparatus.

The evaporator is installed between the indoor fan and the indoor wet curtain apparatus, such that under a drive of the indoor fan, indoor air sequentially flows through the indoor fan, the indoor air supply outlet, the evaporator, the indoor wet curtain apparatus and the indoor return air inlet to form a loop.

The outdoor fan is arranged at an outdoor air outlet of the outdoor subsystem, the outdoor wet curtain apparatus is arranged at an outdoor air inlet of the outdoor subsystem, and the fluorine pump condenser is arranged adjacent to the liquid cooling dry cooler, such that under the drive of the outdoor fan, outdoor air flows through the outdoor wet curtain apparatus, the fluorine pump condenser, the liquid cooling dry cooler and the outdoor fan and is discharged to outside.

The fluorine pump condenser, the compressor, the evaporator, the expansion valve and the fluorine pump are sequentially connected through a coolant pipe to form a coolant loop.

In implementation, as an enclosed environment, the indoor subsystem (or referred to as an indoor portion) is not communicated with the outdoor air, and interiors of the indoor subsystem may be communicated with each other. As an open environment, the outdoor subsystem (or referred to as an outdoor portion) is communicates with the outdoor air. Walls of the indoor subsystem and outdoor subsystem may adopt a single material or a composite material, or may adopt brick walls, aerated concrete block walls, plate walls or the like, and the present disclosure is not limited thereto.

In implementation, a flow direction of air distribution (which may be referred to as the outdoor air) of parts of the outdoor portion is outdoor air→outdoor cooling wet curtain apparatus or outdoor air inlet louver/electric louver→condenser of a fluorine pump system or dry cooler of a cold plate liquid cooling system→outdoor fan→outdoor air. A flow direction of air distribution (which may be referred to as the indoor air) of parts of the indoor portion is indoor return air inlet→indoor fan→evaporator→indoor wet curtain apparatus→indoor air supply outlet.

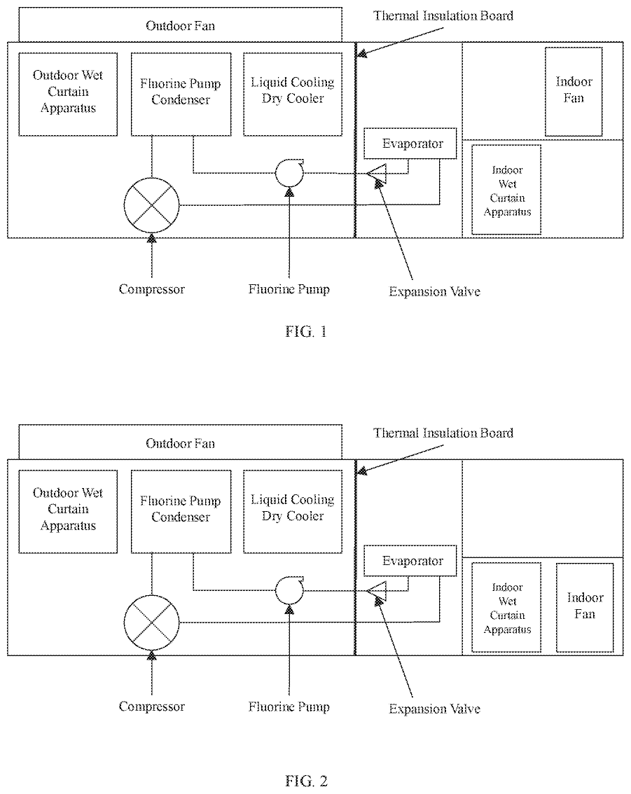

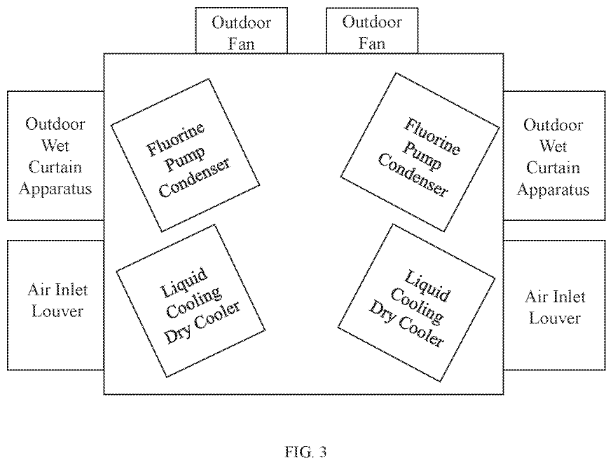

Referring to FIG. 1 and FIG. 2, the indoor fan may be arranged above or behind the indoor wet curtain apparatus, which is not limited in the present disclosure.

Further, a thermal insulation board may be arranged between the indoor subsystem and the outdoor subsystem.

That is, the outdoor portion and the indoor portion may be connected by means of the thermal insulation board. Walls between the indoor subsystem and the outdoor subsystem adopt the thermal insulation board, which not only plays a role in heat insulation, but also makes system construction convenient and fast, and can improve construction efficiency of the data center.

Further, the data center computer room cooling system of the present disclosure may also include a support frame for placing and fixing parts of the indoor subsystem and the outdoor subsystem.

In implementation, the outdoor portion and the indoor portion may be arranged adjacent to a base of the support frame. The support frame may place and fix all parts involved in the data center computer room cooling system, and a pattern or shape of the support frame may be adjusted according to a structural design of the data center computer room cooling system. The support frame may be a spliced frame or an integrated frame. For example, the support frame may be welded with stainless steel and other metals.

Further, the pattern of the support frame may be a single layer or multiple layers. The fluorine pump condenser and the liquid cooling dry cooler may be arranged vertically or horizontally on the support frame. In addition, other relative positional relationships may be employed for the fluorine pump condenser and the liquid cooling dry cooler, which is not limited in the present disclosure.

In implementation, a pipe (not shown in the figure) is connected to the liquid cooling dry cooler, and other parts of the cold plate liquid cooling system are also connected to the pipe, which is not described herein. When flowing through the liquid cooling dry cooler, the outdoor air can cool a liquid in the pipe and reduce a temperature of the liquid in the pipe. The pipe may pass through the indoor portion, thus achieving the objective of indoor heat dissipation. It is to be understood that the outdoor air is cooled by wet curtain before cooling the condenser of the fluorine pump system and the dry cooler of the cold plate liquid cooling system respectively, which is equivalent to a fact that the cooled condenser of the fluorine pump system and the cooled dry cooler of the cold plate liquid cooling system simultaneously provide two different cold sources to the whole cooling system. The condenser of the fluorine pump system can provide a cold source to the indoor evaporator, and cool hard disks and other parts by cooling indoor return air; and the dry cooler of the cold plate liquid cooling system can provide a cold source to indoor cold plate parts to cool CPU and other parts. Number and dimension of the fluorine pump condenser and the liquid cooling dry cooler coil may be equal or may be different, which is not limited in the present disclosure.

Further, the indoor wet curtain apparatus and/or the outdoor wet curtain apparatus comprises a sprinkler pump, a water inlet pipe, a water discharge pipe, a valve, and a water collecting sump. The sprinkler pump is arranged above the indoor wet curtain apparatus and/or the outdoor wet curtain apparatus; the valve is installed on the water inlet pipe or the water discharge pipe; and two ends of the water inlet pipe and two ends of the water discharge pipe are respectively connected to the sprinkler pump and the water collecting sump.

In implementation, when the sprinkler pump is operating, it pumps water from the water collecting sump through the water inlet pipe and supplies water to the wet curtain apparatus. Air around the wet curtain apparatus is cooled and humidified based on principles of water evaporation and heat absorption, and the water is introduced into the water collecting sump through the water discharge pipe by gravity. Reference may be made to industry standard for specific structures of the wet curtain apparatus, which are not described in detail herein.

Further, the outdoor subsystem may also include an outdoor air inlet louver, which is mounted at the outdoor air inlet.

For example, referring to FIG. 3, the outdoor fan, the outdoor wet curtain apparatus and the air inlet louver of the outdoor portion may be arranged on an outer wall of the system. The fluorine pump condenser and the liquid cooling dry cooler may be arranged on the support frame in the system, and parts such as the compressor, the expansion valve and a solenoid valve may also be arranged on the support frame (not shown in FIG. 3). In this embodiment, the outdoor wet curtain apparatus and the air inlet louver may serve as a first passage for the outdoor air to enter the outdoor portion of the unit, and then the outdoor air is discharged out of the system through the outdoor fan.

In implementation, the outdoor air inlet louver may be a manually-controlled louver or an electric louver based on remote control. Flow of the outdoor air entering the outdoor subsystem may be controlled by opening or closing the outdoor air inlet louver and adjusting an opening degree of the outdoor air inlet louver. It is to be understood that when the outdoor air inlet louver is fully opened, the flow of the outdoor air entering the outdoor subsystem is maximum; and when the outdoor air inlet louver is closed, the flow of the outdoor air entering the outdoor subsystem is 0 cfm or is close to 0 cfm

Further, the data center computer room cooling system provided by the present disclosure may also include a unit controller mounted on a side wall of the outdoor subsystem.

In implementation, the data center computer room cooling system provided by the present disclosure may also include associated sensors and control elements of various components, for example, the associated sensors and the control elements of components such as the compressor, the fluorine pump, the dry cooler of the cold plate liquid cooling system, indoor and outdoor fans, indoor and outdoor wet curtain apparatuses, outdoor air inlet louvers. The sensors may be a temperature sensor, a humidity sensor, a gas flowmeter, etc.

The control elements may be uniformly arranged in the unit controller. In this way, the data center computer room cooling system may be operated, overhauled and controlled outdoors by means of the unit controller. These controls may include: control of compressor-fluorine pump, control of the dry cooler of the cold plate liquid cooling system, control of the indoor fan, control of the outdoor fan, control of the indoor humidifying wet curtain apparatus, control of outdoor cooling wet curtain, control of the outdoor air inlet louver/electric louver, etc. Reference may be made to the existing traditional solutions for the control of compressor-fluorine pump, the control of the dry cooler of the cold plate liquid cooling system, the control of the indoor fan, the control of the outdoor fan and the control of the indoor humidifying wet curtain apparatus, which is not described in detail herein.

Further, the coolant loop of the outdoor subsystem is also provided with a cooling water pump, a frequency converter, and a shock absorber.

In implementation, the cooling water pump, related valves, the frequency converter, the shock absorber and so on may be selectively deployed in the outdoor subsystem according to project requirements. The control elements of the cooling water pump may be prefabricated and integrated into the unit controller, such that operating states of the cooling water pump may be controlled outdoors by means of the unit controller. The related valves may be stop valves, check valves, and exhaust valves, etc. The operating states of the cold plate liquid cooling system may be controlled by operating the frequency converter. To avoid damage of the data center computer room cooling system during vibration, the shock absorbers may be arranged at water inlets and outlets of various pipes, and the shock absorbers may also be arranged at joints between various parts and the base of the support frame.

Further, a projection of the indoor wet curtain apparatus on a plane where the indoor air supply outlet is located completely or partially covers the indoor air supply outlet.

In implementation, a dimension of the indoor wet curtain apparatus may not be lower than a cross-sectional dimension of an air supply side, or may be a portion of the cross-sectional dimension of the air supply side. Accordingly, the dimension of the outdoor wet curtain apparatus may also be flexibly set according to the project requirements.

It is worth mentioning that various pipes involved in the data center computer room cooling system may be arranged and connected according to requirements, and may be fixed by integrated pipe supports, which is not described herein.

Based on the same technical idea, an embodiment of the present disclosure also provides a control method for a data center computer room cooling system, where the control method is applied to the data center computer room cooling system. The control method includes:
collecting an outdoor ambient temperature and determining whether the outdoor ambient temperature is lower than a preset temperature threshold;
turning off the outdoor wet curtain apparatus when the outdoor ambient temperature is lower than the preset temperature threshold; and
turning on the outdoor wet curtain apparatus when the outdoor ambient temperature is not lower than the preset temperature threshold.

Further, when the outdoor subsystem is provided with the outdoor air inlet louver, whether the outdoor air enters the outdoor subsystem is controlled by turning on or off the outdoor air inlet louver.

In implementation, the outdoor wet curtain apparatus may be turned on when the outdoor ambient temperature reaches the preset temperature threshold. For example, the outdoor wet curtain apparatus may be turned on when the outdoor environment is harsh (such as hot weather). The outdoor air is cooled by wet curtain first before cooling the condenser of the fluorine pump system and the dry cooler of the cold plate liquid cooling system, to meet the refrigeration demands. When the outdoor ambient temperature is lower, ideal cooling effects may be achieved even though the outdoor wet curtain apparatus, the condenser of the fluorine pump system and the dry cooler of the cold plate liquid cooling system are not operating simultaneously. In this case, the outdoor wet curtain apparatus may be turned off by closing the outdoor air inlet louver/electric louver to cool the outdoor air, or the condenser of the fluorine pump system and the dry cooler of the cold plate liquid cooling system may be controlled correspondingly (for example, adjusting an actual output power), to achieve targeted refrigeration and optimize energy efficiency.

By adopting the above technical solutions, the present disclosure can at least produce following technical effects.

Firstly, cold sources of an air cooling system and cold sources of a liquid cooling system are integrated, and all parts are arranged on one whole support frame, thus achieving integrated delivery of the air cooling system and the liquid cooling system, which can effectively save workload and complexity in construction stages, making a delivery speed more than 25% faster than that of a traditional way. Secondly, by adopting the present disclosure, wet curtain drenching measures can be adopted for an air cooling portion, such that energy efficiency can be improved by 10% to 20% compared with an ordinary large-scale fluorine pump unit. Furthermore, the wet curtain drenching measures and a traditional dry condenser with sufficient capacity are used in a liquid cooling portion, which can ensure that the liquid cooling portion still has sufficient heat dissipation capacity under extreme operating states, and annual operation energy consumption is reduced by more than 10% to 20% compared with the solution of using the traditional dry condenser. Thirdly, according to the present disclosure, the data center computer room cooling system includes the indoor subsystem and the outdoor subsystem, which conforms to a distributed architecture solution of an air conditioner, has better fault tolerance than a traditional capacity unit, and has no fatal influence on the system. Fourthly, when this product is delivered in large scale and in batches, prices of the data center computer room cooling system can be further reduced, which can effectively alleviate a problem of higher prices of cold plate liquid cooling refrigeration systems.

The embodiments described above are only illustrated as preferred embodiments of the present disclosure, and are not intended to limit the present disclosure. All modifications, equivalent substitutions and improvements made within the spirit and principles of the present disclosure shall fall within the protection scope of the present disclosure.

What is claimed is:

1. A data center computer room cooling system comprising an indoor subsystem and an outdoor subsystem, wherein the indoor subsystem comprises an indoor fan, an indoor air supply outlet, an indoor return air inlet, an indoor wet curtain apparatus and an evaporator; the outdoor subsystem comprises an outdoor fan, a fluorine pump condenser, a liquid cooling dry cooler, a compressor, a fluorine pump, an expansion valve, and an outdoor wet curtain apparatus;
the evaporator is installed between the indoor fan and the indoor wet curtain apparatus, such that under a drive of the indoor fan, indoor air sequentially flows through the indoor fan, the indoor air supply outlet, the evaporator, the indoor wet curtain apparatus and the indoor return air inlet to form a loop;
the outdoor fan is arranged at an outdoor air outlet of the outdoor subsystem, the outdoor wet curtain apparatus is arranged at an outdoor air inlet of the outdoor subsystem, and the fluorine pump condenser is arranged adjacent to the liquid cooling dry cooler, such that under the drive of the outdoor fan, outdoor air flows through the outdoor wet curtain apparatus, the fluorine pump condenser, the liquid cooling dry cooler and the outdoor fan and is discharged to outside; and
the fluorine pump condenser, the compressor, the evaporator, the expansion valve and the fluorine pump are sequentially connected through a coolant pipe to form a coolant loop.

2. The system of claim 1, wherein a thermal insulation board is arranged between the indoor subsystem and the outdoor subsystem.

3. The system of claim 1 further comprising a support frame for placing and fixing parts of the indoor subsystem and the outdoor subsystem; wherein the fluorine pump condenser and the liquid cooling dry cooler are arranged vertically or horizontally on the support frame.

4. The system of claim 1, wherein the indoor wet curtain apparatus and/or the outdoor wet curtain apparatus comprises a sprinkler pump, a water inlet pipe, a water discharge pipe, a valve, and a water collecting sump; and
the sprinkler pump is arranged above the indoor wet curtain apparatus and/or the outdoor wet curtain apparatus; the valve is installed on the water inlet pipe or the water discharge pipe; and two ends of the water inlet pipe and two ends of the water discharge pipe are respectively connected to the sprinkler pump and the water collecting sump.

5. The system of claim 1, wherein the outdoor subsystem further comprises an outdoor air inlet louver mounted at the outdoor air inlet.

6. The system of claim 1 further comprising a unit controller mounted on a side wall of the outdoor subsystem.

7. The system of claim 1, wherein the coolant loop of the outdoor subsystem is further provided with a cooling water pump, a frequency converter, and a shock absorber.

8. The system of claim 1, wherein a projection of the indoor wet curtain apparatus on a plane where the indoor air supply outlet is located completely or partially covers the indoor air supply outlet.

9. A control method for a data center computer room cooling system, comprising an indoor subsystem and an outdoor subsystem, wherein the indoor subsystem comprises an indoor fan, an indoor air supply outlet, an indoor return air inlet, an indoor wet curtain apparatus and an evaporator; the outdoor subsystem comprises an outdoor fan, a fluorine pump condenser, a liquid cooling dry cooler, a compressor, a fluorine pump, an expansion valve, and an outdoor wet curtain apparatus; and the control method comprises:
collecting an outdoor ambient temperature and determining whether the outdoor ambient temperature is lower than a preset temperature threshold;
turning off the outdoor wet curtain apparatus when the outdoor ambient temperature is lower than the preset temperature threshold; and
turning on the outdoor wet curtain apparatus when the outdoor ambient temperature is not lower than the preset temperature threshold.

10. The control method of claim 9, wherein when the outdoor subsystem is provided with an outdoor air inlet louver, whether the outdoor air enters the outdoor subsystem is controlled by turning on or off the outdoor air inlet louver.
